(19) United States
(12) Patent Application Publication
(10) Pub. No.: US 2010/0190534 A1
(43) Pub. Date: Jul. 29, 2010

(54) Portable electronic device and charging method thereof

(75) Inventor: Nien-Wan Sun, Taipei Hsien (TW)

Correspondence Address: BACON & THOMAS, PLLC, 625 SLATERS LANE, FOURTH FLOOR, ALEXANDRIA, VA, 22314-1176, US

(73) Assignee: Wistron Corporation, Taipei Hsien (TW)

(21) Appl. No.: 12/458,470

(22) Filed: Jul. 14, 2009

(30) Foreign Application Priority Data
Jan. 23, 2009 (TW) 098102790

(51) Int. Cl. H04B 1/38; H01L 31/042; H01M 10/46

(52) U.S. Cl. 455/573; 136/244; 320/101

(57) ABSTRACT

A portable electronic device and a charging method thereof are disclosed. The portable electronic device comprises an electronic device main body, a power storage module, a moving module, and a first solar panel. The power storage module is used for providing the power for the electronic device main body. The first solar panel is electrically coupled with the power storage module and the first solar panel can move together with the moving module for moving the first solar panel outward. The charging method comprises: detecting a power value of the power storage module; determining whether the power value of the power storage module is under a first specific value; when the power value of the power storage module is under the first specific value, moving the first solar panel outward to charge the power storage module.

### BACKGROUND OF THE INVENTION

1. Field of the Invention

The present invention relates to a portable electronic device and charging method thereof; more particularly, the present invention relates to a portable electronic device for utilizing a moving module to move a solar panel outward to perform a charging procedure, and a method of charging the portable electronic device by means of automatically sliding a sliding member.

2. Description of the Related Art

The power source of a portable electronic device generally comes from a rechargeable battery. In known prior arts, when the rechargeable battery runs out of power, usually the rechargeable battery can be recharged by means of electrically connecting a battery charger to a power socket.

Solar power is a kind of renewable green power sources. No undesirable gases, such as carbon dioxide, will be produced during the solar power generating procedure; therefore, no environmental contamination will be caused. Further, without being limited to a location with an electrical outlet, the solar battery can be recharged as long as there is light. In known prior arts, the solar battery is an optoelectronic semiconductor slice which directly generates power by means of utilizing sunlight, wherein different natures may be formed by means of adding different impurities into a high-purity semiconductor material. For example, a P-type semiconductor can be formed by adding boron into the high-purity semiconductor material, and an N-type semiconductor can be formed by adding phosphorus into the high-purity semiconductor material. When the P-type and the N-type semiconductors are combined together, a large volume of free electrons will be present once there is sunlight, such that an electric current can be generated from the movement of the free electrons. At this time, if the solar battery is connected to an accumulator, all energy generated during sunshine can be stored in advance, such that the energy can be used later, when there is no sunlight.

In recent years, with the development of a greater variety of functions of portable electronic devices, the power consumption of such portable electronic devices has accordingly increased. For example, the power consumption of a personal digital assistant (PDA) cellular phone has been enormously increased because the PDA cellular phone needs to execute numerous application programs, including telephoning, listening to music, viewing images, using a wireless internet access function, and so on. With the increased demand for power, there is also a trend for portable electronic devices to be designed in a compact size. Therefore, if solar energy is going to be applied to a portable electronic device, there is a need to increase the surface area of a solar panel within a limited space, as well as to provide a user with a convenient charging method, so as to supply power to the portable electronic device.

Therefore, there is a need to provide a portable electronic device and a charging method thereof to mitigate and/or obviate the aforementioned problems.

### SUMMARY OF THE INVENTION

It is an object of the present invention to provide a portable electronic device capable of moving a solar panel outward to perform a charging procedure, wherein the present invention utilizes a moving module to move the solar panel outward to charge a power storage module.

It is another object of the present invention to provide a method of charging a portable electronic device by means of automatically sliding a sliding member.

To achieve the aforementioned objects, the portable electronic device comprises an electronic device main body, a power storage module, a moving module, and a first solar panel. The power storage module is used for providing power to the electronic device main body. The first solar panel is electrically coupled with the power storage module, and can move together with the moving module for moving the first solar panel outward.

To achieve another aforementioned object, the automatic charging method used in the portable electronic device of the present invention comprises the steps of detecting a power value of the power storage module; determining whether the power value of the power storage module is under a first specific value; and when the power value of the power storage module is under the first specific value, moving the solar panel outward to charge the power storage module.

According to one preferred embodiment of the present invention, the moving module comprises a gear drive mechanism, and the moving module is connected with a first casing and a second casing of the portable electronic device, wherein the first solar panel is connected with one side of the second casing.

Other objects, advantages, and novel features of the invention will become more apparent from the following detailed description when taken in conjunction with the accompanying drawings.

### BRIEF DESCRIPTION OF THE DRAWINGS

These and other objects and advantages of the present invention will become apparent from the following description of the accompanying drawings, which disclose several embodiments of the present invention. It is to be understood that the drawings are to be used for purposes of illustration only, and not as a definition of the invention.

In the drawings, wherein similar reference numerals denote similar elements throughout the several views:

FIG. 1 illustrates a system architecture of a portable electronic device of the present invention.

FIG. 2 illustrates a schematic drawing of the portable electronic device according to a first embodiment of the present invention.

FIG. 3 illustrates a cross-sectional view of the portable electronic device according to the first embodiment of the present invention.

FIG. 4 illustrates a schematic drawing of the portable electronic device according to a second embodiment of the present invention.

FIG. 5 illustrates a schematic drawing of the portable electronic device according to a third embodiment of the present invention.

FIG. 6 illustrates a schematic drawing of the portable electronic device according to a fourth embodiment of the present invention.

FIG. 7 is a flowchart of a method of charging the portable electronic device by means of automatically sliding a sliding member of the present invention.

### DETAILED DESCRIPTION OF THE PREFERRED EMBODIMENT

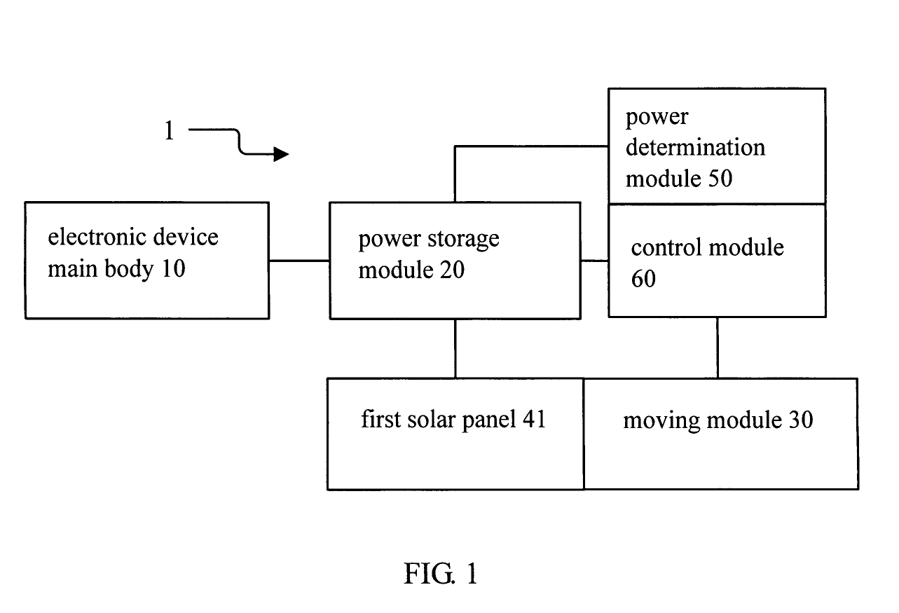

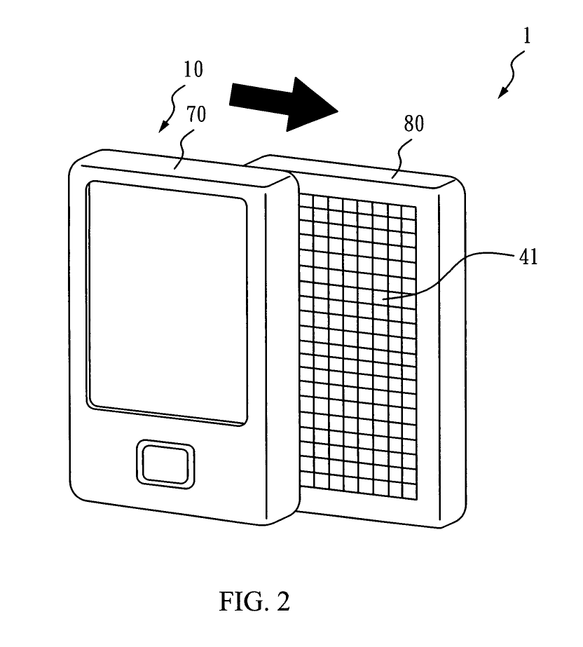

Please refer to both FIG. 1 and FIG. 2. FIG. 1 illustrates a system architecture of a portable electronic device of the present invention. FIG. 2 illustrates a schematic drawing of the portable electronic device according to a first embodiment of the present invention. In this embodiment, the portable electronic device 1 is, but is not limited to, a personal digital assistant (PDA) cellular phone. The portable electronic device of the present invention can also be a digital camera, a handheld game console, a digital camcorder, or other equivalent portable electronic device.

The portable electronic device 1 comprises an electronic device main body 10, a power storage module 20, a moving module 30, a first solar panel 41, a power determination module 50 and a control module 60. The electronic device main body 10 is a primary part that performs the functions of the portable electronic device 1. The power storage module 20 is used for providing power to the electronic device main body 10. The power storage module 20 can be a common rechargeable battery (such as a lithium battery), wherein the power stored in the power storage module 20 is continuously supplied to the electronic device main body 10 for operations, and the power stored in the power storage module 20 will be reduced with the consumption of the electronic device main body 10.

The first solar panel 41 is electrically coupled with the power storage module 20. Therefore, the power generated after the first solar panel 41 absorbs sunlight can be directly transmitted to and stored in the power storage module 20. Further, the first solar panel 41 can move together with the moving module 30. As a result, when the moving module 30 moves, it can drive the first solar panel 41 to move outward or inward accordingly.

The power determination module 50 is used for determining whether a power value of the power storage module 20 is under a first specific value (referring to a low-battery status) or above a second specific value (referring to a full-battery status), so as to determine whether to charge or stop charging the power storage module 20.

The control module 60 is used for controlling the movement of the moving module 30. When the power value of the power storage module 20 is under the first specific value, the control module 60 drives the moving module 30 to move the first solar panel 41 outward to perform a charging procedure. Otherwise, when the power value of the power storage module 20 is above the second specific value, the control module 60 drives the moving module 30 to move the first solar panel 41 inward to stop the charging procedure.

The power determination module 50 and the control module 60 can be two independent elements or modules, or can be combined together as one element or module. Further, the power determination module 50 and the control module 60 can be in the form of hardware (such as a chip), software, firmware, a circuit, or combination thereof.

Please note that when the power of the portable electronic device 1 is low and needs to be charged, the present invention also allows a user to directly move the first solar panel 41 outward by hand, such that the portable electronic device 1 provides both functions of manually and automatically moving the solar panel outward. If the portable electronic device 1 only allows the solar panel to be moved outward manually, then there is no need to install the power determination module 50 and the control module 60 in the present invention.

The arrangement of each structure of the portable electronic device 1 of the present invention will be described hereinafter. As shown in FIG. 2, the portable electronic device 1 comprises a first casing 70 and a second casing 80. The moving module 30 is connected with the first casing 70 and the second casing 80, such that the first casing 70 and the second casing 80 can move relatively. In this embodiment, the first solar panel 41 is located in one side of the second casing 80.

Please note that the location of the first solar panel 41 is not limited to the above description. For example, the first solar panel 41 can be located in another side of the second casing 80, or any side of the first casing 70.

In this embodiment, the power determination module 50 and the control module 60 is disposed in the first casing 70, while the power storage module 20 is disposed to the inside of the second casing 80. Please note that the locations of the power determination module 50, the control module 60 and the power storage module 20 are not limited to the above description.

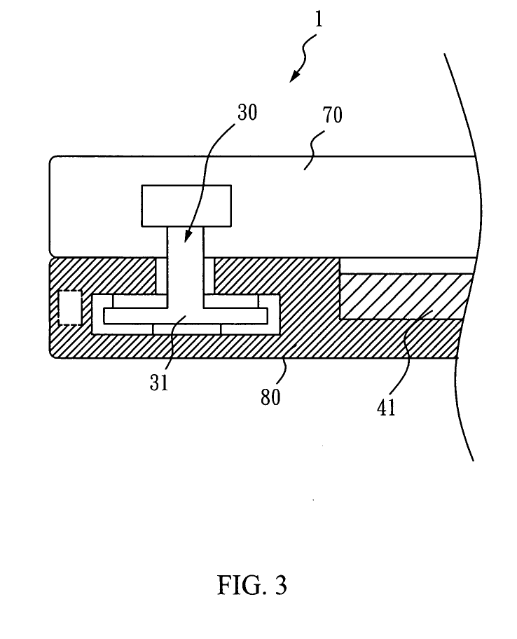

Please refer to FIG. 3, which illustrates a cross-sectional view of the portable electronic device according to the first embodiment of the present invention. In this embodiment, the moving module 30 comprises a gear drive mechanism 31. For example, the gear drive mechanism 31 is a gear set (including a plate gear and a gear rack), which moves the first solar panel 41 (as shown in FIG. 2) outward by means of utilizing a motor to drive the gear set to move. In this embodiment, the first solar panel 41 slides outward from the long edge of the portable electronic device 1. Since the theory of the gear drive mechanism is a known prior art, there is no need to describe the theory in detail.

Please note that the structure of the moving module 30 is not limited to the above description. For example, the moving module 30 can also be an electromagnetic drive mechanism. By means of utilizing the conversion between electric force and magnetic force, and utilizing the fact that like poles repel and opposite poles attract, the electromagnetic drive mechanism can move the first solar panel 41 outward or inward. Since the theory behind the electromagnetic drive is a known prior art, there is no need to describe the theory in detail.

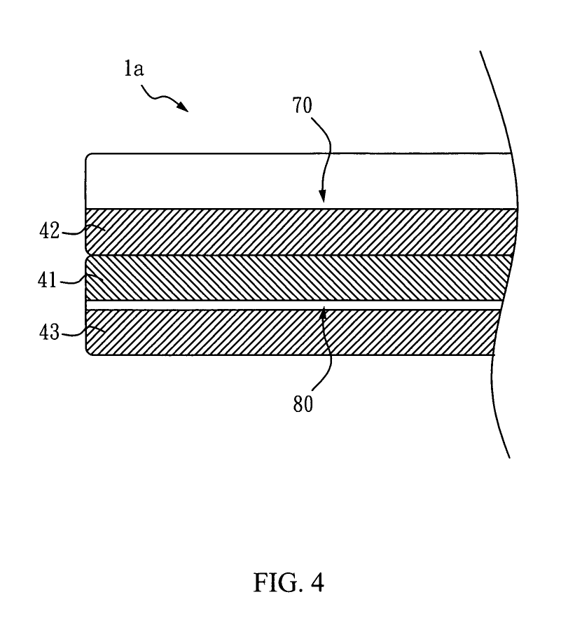

Please refer to FIG. 4, which illustrates a schematic drawing of the portable electronic device according to a second embodiment of the present invention. The major difference between the first embodiment and the second embodiment is that in the second embodiment, the portable electronic device 1a has three solar panels, including a first solar panel 41, a second solar panel 42, and a third solar panel 43. The second solar panel 42 is located on an inner side of the first casing 70, and the third solar panel 43 is located on an outer side of the second casing 80. Therefore, the surface area of the solar panels exposed to sunlight can be increased, so as to enhance power-generating efficiency. Please note that if the surface area of the solar panel is sufficient, then the second solar panel 42 or the third solar panel 43 can be ignored.

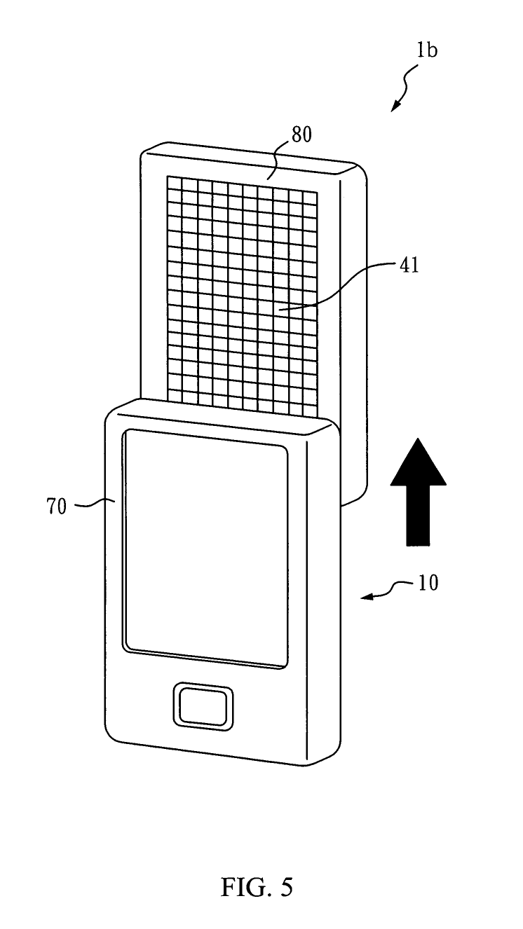

Please refer to FIG. 5, which illustrates a schematic drawing of the portable electronic device according to a third embodiment of the present invention. The major difference between the first embodiment and the third embodiment is that in the third embodiment, the first solar panel 41 of the portable electronic device 1b slides outward from the short edge of the portable electronic device 1b.

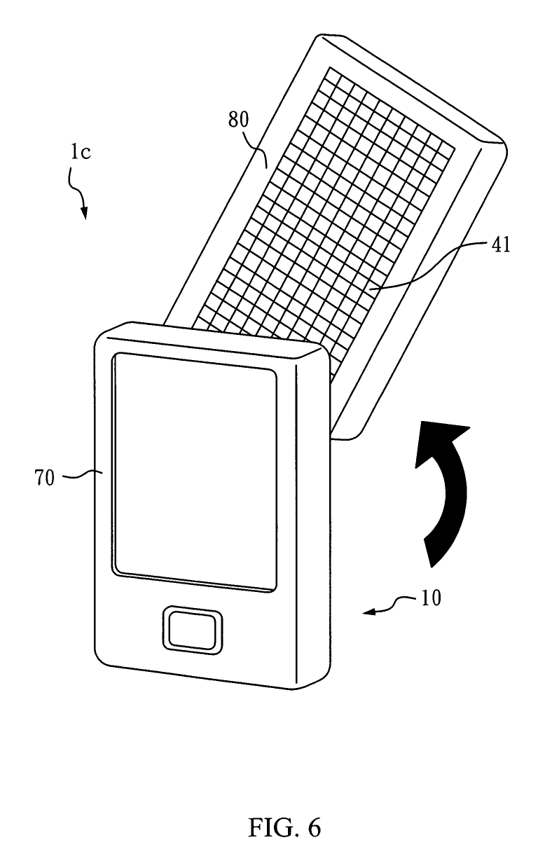

Please refer to FIG. 6, which illustrates a schematic drawing of the portable electronic device according to a fourth embodiment of the present invention. The major difference between the first embodiment and the fourth embodiment is that in the fourth embodiment, the first solar panel 41 moves outward via rotation, wherein a pivot position can be designed in either the short edge or the long edge of the portable electronic device 1c.

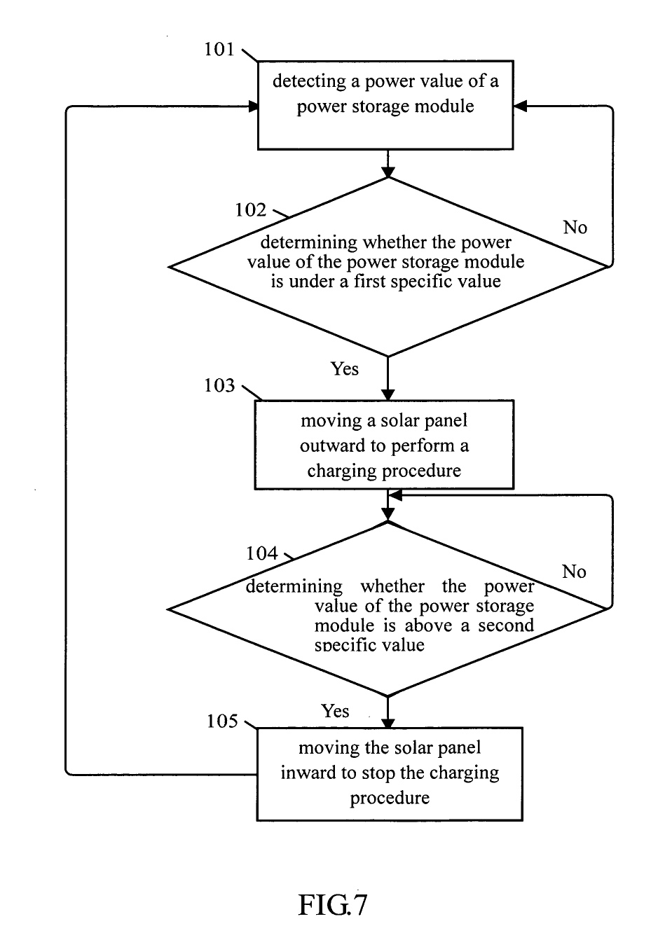

Please refer to FIG. 7, which is a flowchart of a method of charging the portable electronic device by means of automatically sliding a sliding member of the present invention. Each step of the present invention will be described hereinafter.

The present invention firstly performs step 101: detecting a power value of a power storage module.

In step 101, the present invention firstly utilizes the power determination module 50 to detect the power value of the power storage module 20.

Then the present invention performs step 102: determining whether the power value of the power storage module is under a first specific value.

In step 102, the power determination module 50 determines whether the power value of the power storage module 20 is under the first specific value. For example, the first specific value is, but is not limited to, 5%-20% of a maximum stored power of the power storage module 20. When the power determination module 50 determines that the power value of the power storage module 20 is under the first specific value, the power storage module 20 is determined to be in a low-battery status, such that the present invention performs step 103. Otherwise, if the power determination module 50 determines that the power value of the power storage module 20 is not under the first specific value, the present invention returns to step 101 to continue detecting the power value of the power storage module 20.

In step 103, the moving module 30 automatically moves the first solar panel 41 outward (as shown in FIG. 2, FIG. 5 or FIG. 6) to perform a charging procedure.

Furthermore, if the first solar panel 41 has been moved outward (for example, the first solar panel 41 has been manually moved outward by a user by hand), step 102 of the present invention further comprises a sub-step for determining whether the first solar panel 41 has been moved outward. If the first solar panel 41 has not been moved outward, the present invention will move it outward to continue the charging procedure.

Then the present invention performs step 104: determining whether the power value of the power storage module is above a second specific value.

In step 104, the power determination module 50 determines whether the power value of the power storage module 20 is above the second specific value. If the power value of the power storage module 20 is above the second specific value, the charging procedure is regarded as complete, and then the present invention performs step 105. In this embodiment, the second specific value is, but is not limited to, 90%-100% of the maximum stored power of the power storage module 20.

If the power value of the power storage module 20 is not above the second specific value, the charging procedure is not complete; therefore, the present invention will repeatedly perform step 104 to continue detecting the power value of the power storage module 20 during the charging procedure.

If the first solar panel 41 has been moved inward (for example, the first solar panel 41 has been manually moved inward by the user by hand), step 104 of the present invention further comprises a sub-step for determining whether the first solar panel 41 has been moved inward. If the first solar panel has not been moved inward, the present invention will move it inward to stop the charging procedure.

In step 105, the moving module 30 automatically moves the first solar panel 41 inward to stop the charging procedure. After step 105, the present invention then returns to step 101 to continue detecting the power value of the power storage module 20.

Although the present invention has been explained in relation to its preferred embodiments, it is to be understood that many other possible modifications and variations can be made without departing from the spirit and scope of the invention as hereinafter claimed.

What is claimed is:

1. A portable electronic device, comprising:
an electronic device main body;
a power storage module, used for providing power to the electronic device main body;
a moving module; and
a first solar panel, electrically coupled with the power storage module, the first solar panel moving together with the moving module for moving the first solar panel outward.

2. The portable electronic device as claimed in claim 1, further comprising:
a power determination module, used for determining whether a power value of the power storage module is under a first specific value; and
a control module, used for driving the moving module to move the first solar panel outward when the power value of the power storage module is under the first specific value.

3. The portable electronic device as claimed in claim 2, wherein the moving module comprises a gear drive mechanism or an electromagnetic drive mechanism.

4. The portable electronic device as claimed in claim 2, further comprising a first casing and a second casing, wherein the moving module is connected with the first casing and the second casing, and the first solar panel is located in one side of the first casing.

5. The portable electronic device as claimed in claim 4, further comprising a second solar panel located in another side of the first casing.

6. The portable electronic device as claimed in claim 4, further comprising a third solar panel located in one side of the second casing.

7. The portable electronic device as claimed in claim 5, further comprising a third solar panel located in one side of the second casing.

8. The portable electronic device as claimed in claim 4, wherein the power determination module and the control module are disposed in the first casing, and the power storage module is disposed the second casing.

9. The portable electronic device as claimed in claim 4, wherein the first solar panel moves outward via sliding or rotating.

10. The portable electronic device as claimed in claim 5, wherein the first solar panel moves outward via sliding or rotating.

11. A charging method capable of sliding automatically, used for an electronic device having a power storage module and a solar panel, the method comprising the steps of:
(A) detecting a power value of the power storage module;
(B) determining whether the power value of the power storage module is under a first specific value; and
(C) when the power value of the power storage module is under the first specific value, moving the solar panel outward to charge the power storage module.

12. The method as claimed in claim 11, further comprising the step of:
determining whether the solar panel has been moved outward.

13. The method as claimed in claim 11, wherein the solar panel is moved outward by means of a gear drive mechanism or an electromagnetic drive mechanism.

14. The method as claimed in claim 12, wherein the solar panel is moved outward by means of a gear drive mechanism or an electromagnetic drive mechanism.

15. The method as claimed in claim 11, further comprising the steps of:
(D) determining whether the power value of the power storage module is above a second specific value; and
(E) when the power value of the power storage module is above the second specific value, moving the solar panel inward.

16. The method as claimed in claim 12, further comprising the steps of:
(D) determining whether the power value of the power storage module is above a second specific value; and
(E) when the power value of the power storage module is above the second specific value, moving the solar panel inward.

17. The method as claimed in claim 15 further comprising the step of:
determining whether the solar panel has been moved inward.

18. The method as claimed in claim 16 further comprising the step of:
determining whether the solar panel has been moved inward.

19. The method as claimed in claim 11, wherein the first specific value is 5%-20% of a maximum stored power of the power storage module.

20. The method as claimed in claim 15, wherein the second specific value is 90%-100% of a maximum stored power of the power storage module.
